(19) United States
(12) Patent Application Publication
(10) Pub. No.: US 2006/0076681 A1
(43) Pub. Date: Apr. 13, 2006

(54) SEMICONDUCTOR PACKAGE SUBSTRATE FOR FLIP CHIP PACKAGING

(75) Inventors: Pei-Haw Tsao, Taichung (TW); Chender Huang, Kaohsiung (TW); Chao-Yuan Su, Kaohsiung (TW)

Correspondence Address: BIRCH STEWART KOLASCH & BIRCH, PO BOX 747, FALLS CHURCH, VA, 22040-0747, US

(73) Assignee: TAIWAN SEMICONDUCTOR MANUFACTURING CO., LTD.

(21) Appl. No.: 10/962,455

(22) Filed: Oct. 13, 2004

(51) Int. Cl. H01L 23/52; H01L 23/48; H01L 23/495

(52) U.S. Cl. 257/758; 257/786; 257/676

(57) ABSTRACT

A substrate of semiconductor package for flip chip package is provided. The substrate comprises a plurality of bump pads; a solder mask layer covering a portion of the plurality of bump pads; and a plurality of dummy anchor plugs coupled beneath the bump pads.

### BACKGROUND

The present invention relates generally to flip chip packaging technology, and more particularly, to substrate structures for flip chip packaging.

Flip chip package is an advanced type of integrated circuit packaging technology that allows the overall package size to be made very compact. By flip chip package, the semiconductor chip is mounted in an upside-down manner over a substrate formed with an array of bump pads, and which is mechanically bonded and electrically coupled to the substrate by means of solder bumps. Conventional type of substrate bump pad design can be classified into SMD (Solder Mask Define) type and NSMD (Non Solder Mask Define) type. Both employ a solder mask layer that covers a portion of the bump pads and prevents shorting between solder bumps. The difference between the two types is that the diameter of the bump pad opening in the solder mask layer of the NSMD type is typically larger than that of the bump pad opening in the solder mask layer of the SMD type. Also, in the NSMD type pad design, an edge of the bump pad is typically exposed.

FIGS. 1 and 2 are cross-sectional views of flip chip packages taking SMD and NSMD, respectively as examples according to the prior art. A plurality of solder bumps 102 (only one is shown in FIGS. 1 and 2) are formed on the active surface 101 of a semiconductor chip 100. The flip chip package configuration includes a substrate 108 which is provided with an array of bump pads 106 (only one bump pad is shown in FIGS. 1 and 2) and may be provided with one or more conductive layers 110 between dielectric material 107 of substrate 108. The substrate 108 has its surface coated with a solder mask layer 104 and exposes only portions of the bump pads. In this way, the chip 100 has its active surface 101 attached to the substrate 108 and is electrically connected to bump pads 106 by its bumps 102. In the NSMD type, an edge of the bump pad is exposed.

An underfill material 115 may be employed to fill the space between the chip 100 and the substrate 108. This is to protect the bumps 102 from premature failure due to bump cracks from the thermal stress resulting from the difference between the coefficient of thermal expansion of the chip 100 and that of substrate 108.

A drawback in the SMD type substrate bump pad design is that frequently during subsequent package processing, a crack 111 may develop in the solder bump near the surface of the solder mask due to the stress concentration at the sharp corner between the solder bump and the solder mask. This crack problem may be further exacerbated and lead to bump joint failure. In the NSMC type substrate bump pad design, a similar problem is often seen. Due to the low adhesion strength of the small bump pad area, frequently the bump pad 106 peels 112 causing delamination of the solder bump from the substrate thereby compromising the flip chip package integrity. As the density of semiconductor devices becomes increasingly higher resulting in increased stress per unit area, the solder bump crack and the bump pad peeling off problems become increasingly profound.

In view of these and other deficiencies in conventional methods for fabrication flip chip packages, improvements in substrates, and in fabrication methods for flip chip packages, are needed in the art.

### SUMMARY

The present invention is directed to a substrate of semiconductor package for flip chip package. In one embodiment, the substrate comprises a plurality of bump pads; a solder mask layer covering a portion of the plurality of bump pads; and a plurality of dummy anchor plugs coupled beneath the bump pads.

### BRIEF DESCRIPTION OF THE DRAWINGS

The features, aspects, and advantages of the present invention will become more fully apparent from the following detailed description, appended claims, and accompanying drawings in which:

FIG. 1 is a cross-sectional view of a flip chip package taking SMD as an example according to the prior art.

FIG. 2 is a cross-sectional view of a flip chip package taking NSMD as an example according to the prior art.

FIG. 3 is a cross-sectional view of a flip chip package taking NSMD as an example according to one embodiment of the present invention.

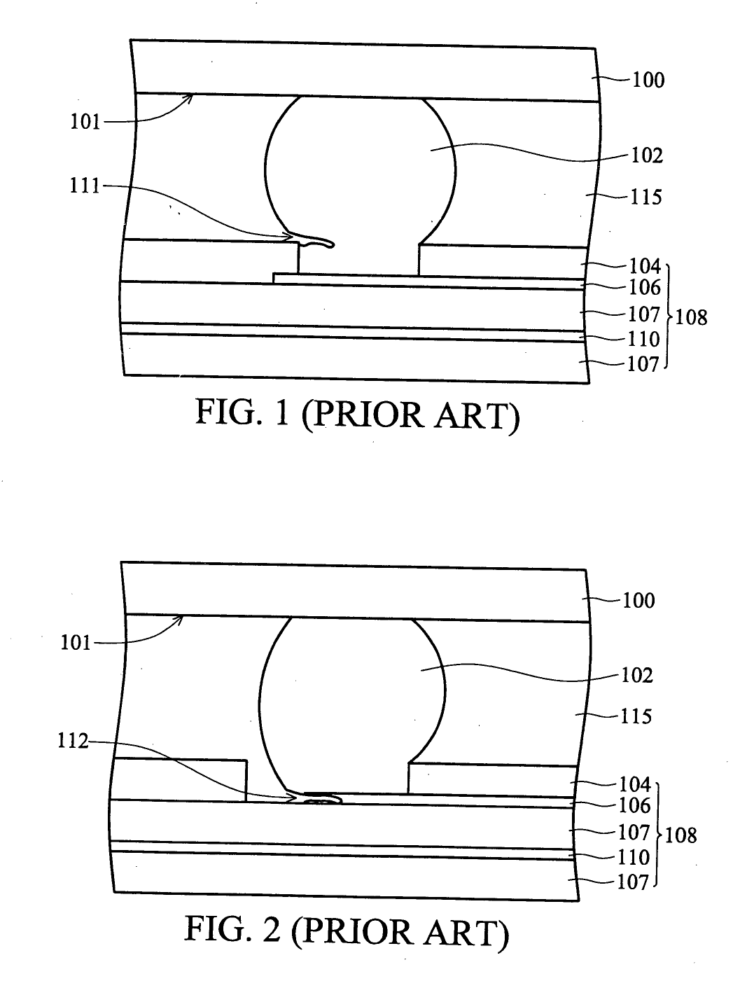

### DETAILED DESCRIPTION

In the following description, numerous specific details are set forth to provide a thorough understanding of the present invention. However, one having an ordinary skill in the art will recognize that the invention can be practiced without these specific details. In some instances, well-known structures and processes have not been described in detail to avoid unnecessarily obscuring the present invention.

Reference will now be made in detail to the present embodiments of the invention, examples of which are illustrated in the accompanying drawings.

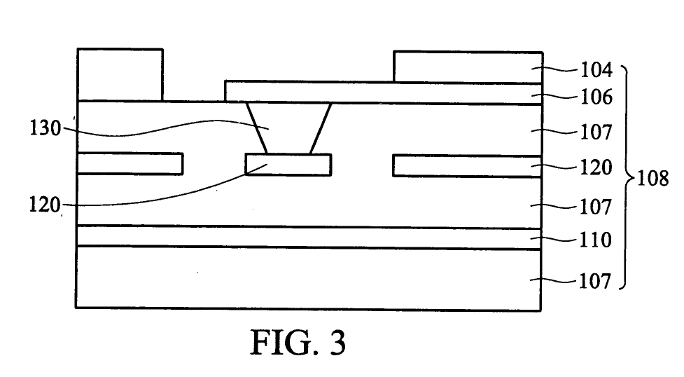

FIG. 3 is a cross-sectional view of a flip chip package taking NSMD as an example according to one embodiment of the present invention. The flip chip package includes a semiconductor chip (not shown) mounted in a flip chip manner over a substrate 108, and which is mechanically bonded and electrically coupled to the substrate 108 by means of a plurality of solder bumps 102 (not shown). Substrate 108 may comprise of plastic substrates or ceramic substrates, for example, and in general, an organic type substrate is preferable for lower cost and superior dielectric property whereas an inorganic type substrate is preferable when high thermal dissipation and matched coefficient of thermal expansion are desired. The term “substrate” as used herein is defined to have at least one or more conductive layers 110 between dielectric material 107. As is understood, the conductive layers 110 may function as signal, power, and/or ground layers.

The substrate 108 has its surface coated with a solder mask layer 104 and exposes only portions of bump pads 106. As shown in FIG. 3, the NSMD type substrate bump pad design has an edge of the bump pad 106 exposed. Bump pad 106 is formed by conventional photolithographic and etching processes and comprises a conductive material such as, for example copper or aluminum. Solder mask 104 covers a portion of bump pad 106 and defines the location of the bump pads. The material for forming solder mask layer 104 is a solder resistant material that may include ultraviolet type of solder mask and thermoset type of solder mask and the method for forming solder mask layer 104 may include, for example roller coating, curtain coating, screen curtain, dipping, and dry film.

To increase the bump pad area adhesion strength and stability thereby decreasing the occurrence of solder bump cracks and bump pad peelings associated with the prior art flip chip package structures, one important aspect of the present invention is the use of a plurality of dummy anchor plugs 130 (FIG. 3 shows one dummy anchor plug) under the bump pads 106. Initially, dummy anchor plugs 130 are via holes that may be formed by various techniques including mechanical drilling, punching, plasma etching, laser drilling or photo etching processes. The via holes are formed at locations that can be aligned with bump pads 106 and when the via holes are subsequently deposited with a conductive material, they provide for the structural integrity of the flip chip package of the present invention. The via holes may extend through one or several layers of dielectric material 107 and conductive layers 110 in substrate 108. While the via hole shown in FIG. 3 has the shape of an inverted triangle, it is understood that the via hole may have any shape and therefore the shape as well as the extension of the via holes in dielectric layer 107 of substrate 108 are design choices dependent on the fabrication process being employed. An electrically conductive material is thereafter deposited into the via holes to form dummy anchor plugs 130 by conventional deposition processes including for example, solder paste printing, solder jetting and solder particle placement. In one embodiment, a dummy anchor plug 130 is formed under every bump pad 106 of substrate 108. In another embodiment, there may be more than one dummy anchor plug 130 formed under each bump pad 106. Dummy anchor plug 130 may optionally be in contact with a dummy metal pad 120 to give bump pad 106 additional support. Although FIG. 3 shows dummy anchor plug 130 being employed in NSMD type substrate bump pad design, dummy anchor plug 130 may also be used in SMD type substrate bump pad design.

In the preceding detailed description, the present invention is described with reference to specifically exemplary embodiments thereof. It will, however, be evident that various modifications, structures, processes, and changes may be made thereto without departing from the broader spirit and scope of the present invention, as set forth in the claims. The specification and drawings are, accordingly, to be regarded as illustrative and not restrictive. It is understood that the present invention is capable of using various other combinations and environments and is capable of changes or modifications within the scope of the inventive concept as expressed herein.

1. A substrate of a semiconductor package for flip chip packaging, comprising:
a plurality of bump pads;
a solder masking layer covering a portion of the plurality of bump pads; and
a plurality of dummy anchor plugs coupled beneath the bump pads.

2. The substrate of claim 1, wherein the substrate comprises SMD (Solder Mask Define) bump pad design.

3. The substrate of claim 1, wherein the substrate comprises NSMD (Non Solder Mask Define) bump pad design.

4. The substrate of claim 1, wherein the dummy anchor plugs are formed by a laser drilling process.

5. The substrate of claim 1, wherein the dummy anchor plugs are formed by a photo etching process.

6. (cancelled)

7. A semiconductor package structure, comprising:
a chip having at least an active surface;
a plurality of bumps disposed on the active surface of the chip;
a substrate comprising a solder mask layer, a plurality of bump pads, and at least one conductive layer, the solder mask layer covering a portion of the bump pads, the chip having its active surface attached to the substrate by coupling the bumps to the uncovered portions of the bump pads; and
a plurality of dummy anchor plugs coupled beneath the bump pads.

8. The semiconductor package structure of claim 7, wherein the substrate comprises SMD (Solder Mask Define) bump pad design.

9. The semiconductor package structure of claim 7, wherein the substrate comprises NSMD (Non Solder Mask Define) bump pad design.

10. The semiconductor package structure of claim 7, wherein the dummy anchor plugs are connected to the at least one conductive layer.

11. The semiconductor package structure of claim 7, wherein the plugs are formed by a laser drilling process.

12. The semiconductor package structure of claim 7, wherein the plugs are formed by a photo etching process.

13. The semiconductor package structure of claim 7, wherein the dummy anchor plugs are coupled to a plurality of dummy metal layers.

14. The semiconductor package structure of claim 7, further comprising an underfill material filling a space between the chip and the substrate.
